(19) United States
(12) Patent Application Publication
(10) Pub. No.: US 2011/0186341 A1
(43) Pub. Date: Aug. 4, 2011

(54) STRUCTURE, ELECTRONIC DEVICE, AND CIRCUIT BOARD

(76) Inventor: Naoki Kobayashi, Tokyo (JP)

(21) Appl. No.: 13/119,254

(22) PCT Filed: Oct. 16, 2009
(86) PCT No.: PCT/JP2009/005423

§ 371 Date: Mar. 16, 2011

(30) Foreign Application Priority Data
Oct. 17, 2008 (JP) 2008-269126

(51) Int. Cl. H05K 1/11

(52) U.S. Cl. 174/266; 174/261

(57) ABSTRACT

A unit cell (106) of a structure (100) has a plurality of first conductors (2), a second conductor (1), a third conductor (3), and a plurality of connective conductors (4). The first conductors (2) are located in a first layer (20), and are separated from each other. The second conductor (1) is located in a second layer (10) which is different from the first layer (20), and is provided so as to have at least a part thereof fallen in a region opposed to the plurality of first conductors (2). The third conductor (3) is located in a third layer (30) located opposite to the second layer (10) while placing the first layer (20) in between, and are opposed to every adjacent ones of the plurality of first conductors (2). The connective conductors (4) respectively connect the third conductors (3) with the plurality of first conductors (2) which overlap the third conductors (3) in a plan view.

### TECHNICAL FIELD

The present invention relates to a structure having characteristics as a meta-material, an electronic device, and a circuit board.

### BACKGROUND ART

One of conventionally-known transmission line structures has a pair of conductors opposed to each other, so as to use the space between the conductors as a medium which allows therethrough transmission of electromagnetic wave. If the transmission line structure has no discontinuous portion, the electromagnetic wave can propagate without causing reflection, while allowing some degree of transmission loss. In recent years, a filter structure which is configured by intentionally providing a discontinuous portion on the transmission line, aiming at reflecting a specific frequency of electromagnetic wave, has been adopted. By virtue of this configuration, in an exemplary case where devices are integrated, unnecessary interference may be prevented from being induced, even if unnecessary electromagnetic wave emitted from peripheral devices were accidentally picked up by a specific transmission line.

The above-described filter structure is typically given as illustrated in FIG. 14 and FIG. 15. FIG. 14 is a plan view illustrating an exemplary configuration of the filter structure making use of a lumped element, while adopting a micro-strip structure to the transmission line, wherein reference numeral 102 stands for a micro-chip, 101 for a circuit element, 104 for a branched line for configuring the filter, and 103 for a clearance hole allowing therein coupling of the filter circuit to the ground. FIG. 15 is a plan view illustrating an exemplary configuration of the filter structure making use of a transmission line stub, wherein reference numeral 201 stands for a stub line. Related examples of such filter structures are disclosed in Patent Documents 1 and 2 below.

On the other hand, it has recently been made clear that propagation characteristics of electromagnetic wave may be controllable by periodically arranging second conductor patterns having a specific structure (referred to as “meta-material”, hereinafter). The meta-material has a band gap frequency range, and does not allow electromagnetic wave having frequency in this range to propagate therethrough.

The meta-material may be used as a filter. Prior arts relevant to this sort of filter include an art described in Patent Document 3, for example. The art described in Patent Document 3 relates to a structure having a plurality of island-like second conductor patterns arranged above a sheet-like second conductor pattern, wherein each of the island-like second conductor patterns is connected through a via to the sheet-like second conductor pattern.

### [Prior Art Documents]

### [Patent Documents]

[Patent Document 1] Japanese Laid-Open Patent Publication No. 2000-101377

[Patent Document 2] Japanese Laid-Open Patent Publication No. 2006-253929

[Patent Document 3] U.S. Pat. No. 6,262,495

### DISCLOSURE OF THE INVENTION

### Problems to be Solved by the Invention

By the way, many of the above-described filter structures are designed to have circuit elements such as inductance and capacitance mounted at the discontinuous portion, so as to determine frequency at which the propagation of electromagnetic wave is blocked making use of resonance between two elements. In general, many of the case, where lumped elements are used as the inductance and capacitance, may fail in obtaining desired filter characteristics in high frequency range (order of GHz or above), due to parasitic inductance or parasitic capacitance. Necessity of mounting dedicated pads also results in increase in the area for mounting.

In order to ensure desirable filter characteristics in the high frequency range, the filter is often designed to make use of resonance which depends on the structure containing transmission line stub and so forth. Even for the case where the stub structure is adopted, increase in the area for mounting is inevitable since the plurality of transmission lines are additionally mounted on either lateral side of the transmission line. In short, whichever of the conventional lumped element and the transmission line stub should be adopted, problems still remain in that desired filter characteristics may be obtained only with difficulty in the high frequency range, only to result in increased area for mounting even if the desired filter characteristics should otherwise be obtained.

To cope with the problems, a possible measure may relate to a filter which is configured making use of the band gap frequency range of the meta-material. The meta-material disclosed in Patent Document 1, however, needs a large area in order to lower the band gap frequency range suitable for the practical use.

It is therefore an object of the present invention to provide a structure having characteristics of a meta-material, and being successfully prevented from increasing in size despite an effort of lowering the band gap frequency range, and also to provide an electronic device and a circuit board making use of the structure.

### Means for Solving the Problems

According to the present invention, there is provided a structure which includes:

a plurality of first conductors which are located in a first layer and are repetitively arranged while being separated from each other;

a second conductor which is located in a second layer different from the first layer, and is provided so as to have at least a part thereof in a region opposed to the plurality of first conductors;

a third conductor which is located in a third layer located opposite to the second layer while placing the first layer in between, and are opposed to each of the plurality of first conductors placed adjacent to each other; and

a plurality of connective conductors which connect the third conductor with the plurality of first conductors opposed to the third conductor.

According to the present invention, there is also provided an electronic device which includes:

an electronic element; and

a circuit board having the electronic element mounted thereon,

the circuit board comprising:

a plurality of first conductors which are located in a first layer and are repetitively arranged while being separated from each other;

a second conductor which is located in a second layer different from the first layer, and is provided so as to have at least a part thereof in a region opposed to the plurality of first conductors;

a plurality of third conductors which are located in a third layer located opposite to the second layer while placing the first layer in between, and are opposed to each of the plurality of first conductors placed adjacent to each other; and

a plurality of vias which connect the respective third conductors with the plurality of first conductors opposed to the third conductors. Either one of the first layer and the second layer has a power source pattern through which source potential is supplied to the electronic element, and the other has a ground pattern through which ground potential is supplied to the electronic element.

According to the present invention, there is also provided a circuit board which includes:

a plurality of first conductors which are located in a first layer and are repetitively arranged while being separated from each other;

a second conductor which is located in a second layer different from the first layer, and is provided so as to have at least a part thereof in a region opposed to the plurality of first conductors;
a plurality of third conductors which are located in a third layer located opposite to the second layer while placing the first layer in between, and are opposed to each of the plurality of first conductors placed adjacent to each other; and
a plurality of vias which connect the respective third conductors with the plurality of first conductors opposed to the third conductors. Either one of the first layer and the second layer has a power source pattern through which source potential is supplied, and the other has a ground pattern through which ground potential is supplied.

### Effect of the Invention

According to the present invention, a structure having characteristics of a meta-material, and being successfully prevented from increasing in size despite an effort of lowering the band gap frequency range, and an electronic device and a circuit board making use of the structure, can be provided.

### BRIEF DESCRIPTION OF THE DRAWINGS

FIG. 1 is a schematic drawing illustrating a configuration of a first embodiment, where (a) is a transverse sectional view, and (b) is a plan view;

FIG. 2 is a drawing explaining a structure, where (a) is a transverse sectional view corresponded to FIG. 1(a), and (b) is an equivalent circuit diagram of the structure;

FIG. 3 is a sectional view illustrating a configuration of a structure of a second embodiment;

FIGS. 4(a) and (b) are plan views-illustrating configurations of unit cells;

FIG. 5 is a graph illustrating results of calculation of absolute values of transmission coefficient;

FIG. 6 is a plan view explaining a structure of a third embodiment;

FIG. 7 is a graph illustrating results of calculation of absolute values of a transmission coefficient;

FIG. 8 is a sectional view illustrating a configuration of a structure of a fourth embodiment;

FIG. 9 is a plan view illustrating a configuration of a structure of a fifth embodiment;

FIG. 10 is a vertical sectional view illustrating a configuration of a structure of a sixth embodiment;

FIG. 11(a) is a plan view illustrating a structure of a seventh embodiment, and (b) is a plan view illustrating a modified example of the structure illustrated in (a);

FIG. 12 is a plan view illustrating a configuration of a structure of an eighth embodiment;

FIG. 13 is a sectional view illustrating a configuration of an electronic device according to a ninth embodiment;

FIG. 14 is a drawing illustrating an exemplary filter structure; and

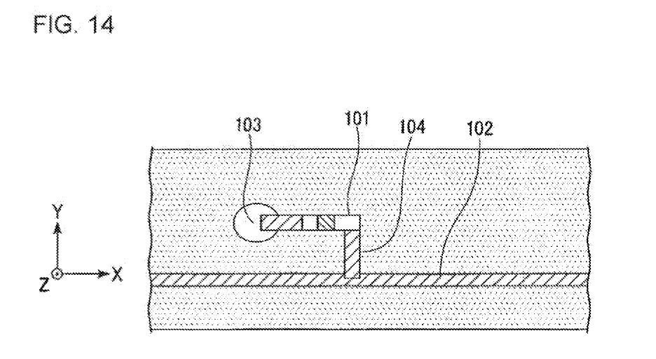

FIG. 15 is a drawing illustrating an exemplary filter structure.

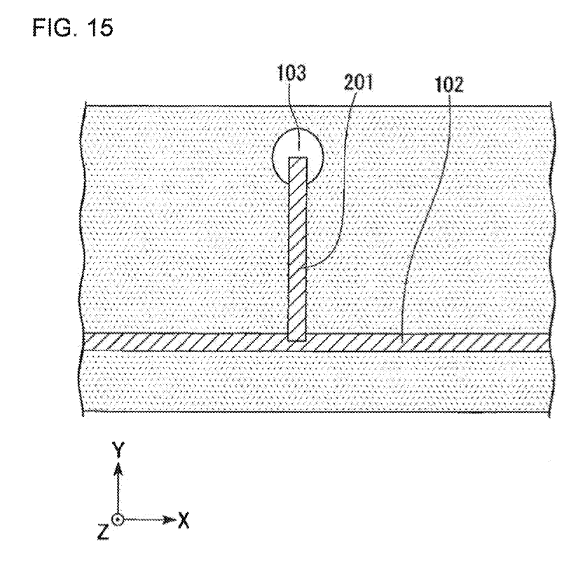

### DETAILED DESCRIPTION OF THE INVENTION

Embodiments of the present invention will be explained below, referring to the attached drawings. Note that all similar constituents in all drawings will be given similar reference numerals or symbols, so as to occasionally avoid repetitive explanation.

### First Embodiment

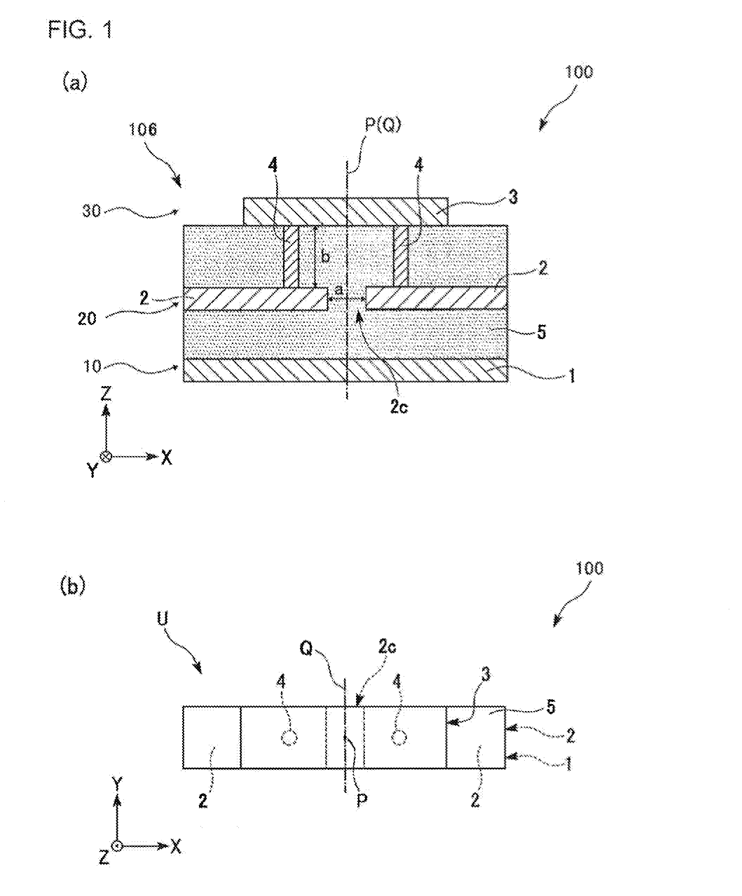

FIG. 1 is a schematic drawing illustrating a configuration of a structure 100 according to the first embodiment, where FIG. 1(a) is a transverse sectional view, and FIG. 1(b) is a plan view. In FIG. 1 to FIG. 12, the planar direction is defined as XY-direction, the height-wise direction (direction of stacking of the layers) as Z-direction, the center axis aligned in the Z-direction of the structure 100 as P, and a plane in YZ-direction as a reference plane Q.

As illustrated in FIG. 1, the structure 100 has a unit cell 106. The unit cell 106 has a plurality of, or typically two, first conductors 2, a second conductor 1, a third conductor 3, and a plurality of connective conductors 4. The first conductors 2 are located in a first layer 20, and are separated from each other. The second conductor 1 is located in a second layer 10 which is different from the first layer 20, and is provided so as to have at least a part thereof in a region opposed to the plurality of first conductors 2. The third conductor 3 is located in a third layer 30 located opposite to the second layer 10 while placing the first layer 20 in between, and is opposed to each of the plurality of first conductors 2 placed adjacent to each other. The connective conductors 4 connect the third conductor 3 to the plurality of first conductors 2 opposed to the third conductor 3. In the example illustrated in the drawing, the connective conductors 4 are via-like components, each of which is provided to a combination of one first conductor 2 and one third conductor 3. The connective conductor 4 is disposed at the center of a region where one first conductor 2 and one third conductor 3 are opposed. The description below will deal with a case where the unit cell 106 has two first conductors 2.

The second layer 10 is located lower than the first layer 20, and extends in the X-direction (in other words, in the direction of a first line). The first layer 20 is placed adjacent to the second layer 10 in the height-wise direction, while keeping a space in between. The first layer 20 has, as described in the above, two first conductors 2 placed adjacent to each other in the X-direction while placing a slit (space) 2c in between. The slit 2c is formed so as to locate the reference plane Q at the center thereof in the X-direction. The reference plane Q is given in the YZ-direction (or in the direction orthogonal to the first line). Width of the slit 2c, or distance “a” between the end faces of two first conductors 2 placed adjacent to each other, is smaller than distance “b” between the first conductor 2 and the third conductor 3. The plurality of first conductors 2, the second conductor 1, and the third conductor 3 configure a transmission line for electromagnetic wave.

The third conductor 3 is placed in adjacent to the first layer 20 in the height-wise direction (Z-direction), while keeping a space in between. The third conductor 3 overlaps, as illustrated in FIG. 1(b), a part of each of two first conductors 2 across the slit 2c in a plan view. In other words, the first conductors 2 and the third conductor 3 are arranged in a staggered manner. In the illustrated example, each of two first conductors 2 placed adjacent to each other has the same area in the portions overlapped with the third conductor 3 in a plan view. The connective conductors 4 are aimed at electrically connecting the first conductors 2 with the third conductor 3, and extend in the height-wise direction (Z-direction).

In the illustrated example, a dielectric 5 is provided between the first layer 20 and the second layer 10, and between the first layer 20 and the third layer 30.

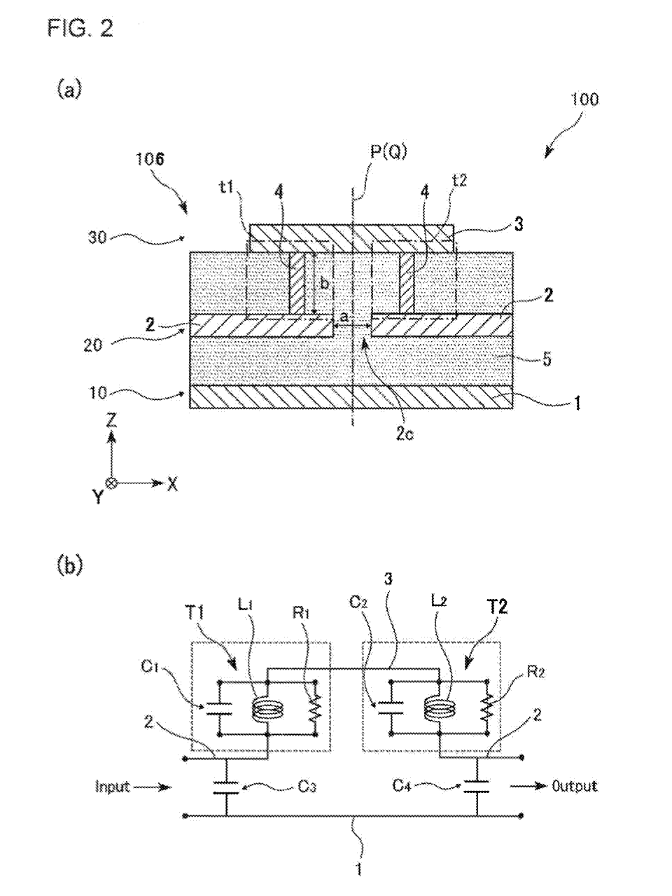

Next, operations of the structure 100 will theoretically be explained. FIG. 2 is a drawing for explaining the structure 100, wherein FIG. 2(a) is a transverse sectional view corresponded to FIG. 1(a), and FIG. 2(b) is an equivalent circuit diagram of the structure 100. Assuming now, as illustrated in FIG. 2(a), that a region in the unit cell 106, which falls between the primary first conductor 2 and the third conductor 3 as region t1, and a region which falls between the secondary first conductor 2 and the third conductor 3 as region t2, the regions t1 and t2 may be represented by a parallel resonant equivalent circuit T1 and parallel resonant equivalent circuit T2, respectively, as illustrated in FIG. 2(b).

In the equivalent circuit T1, first capacitance C₁ is formed between the first conductor 2 and the third conductor 3, and inductance L₁ and resistance R₁ are formed by the connective conductor 4 between the first conductor 2 and the third conductor 3. Similarly, in the equivalent circuit T2, first capacitance C₂ is formed between the first conductor 2 and the third conductor 3, and inductance L₂ and resistance R₂ are formed by the connective conductor 4 between the first conductor 2 and the third conductor 3. Second capacitances C₃, C₄ are formed between the first conductors 2 and the second conductor 1. Resonant frequency of the equivalent circuit T1 is determined by C₁, C₃, R₁ and L₁, whereas resonant frequency of the equivalent circuit T2 is determined by C₂, C₄, R₂ and L₂. Accordingly, the resonant frequency of each of the resonance equivalent circuits T1 and T2 is typically adjustable based on the area of the overlapped region of the first conductors 2 and the third conductor 3, and layout of the connective conductors 4. This indicates that the resonant frequencies fall in the cut-off frequency range of the structure 100 which functions as a filter, or in the band-gap frequency range. In other words, the structure 100 exhibits characteristics of a meta-material. If two adjacent first conductors 2 are configured to have the same area of overlapping with the third conductor 3 in a plan view as illustrated in FIG. 1, the equivalent circuit T1 and the equivalent circuit T2 may be made identical, and thereby cut-off effect of electromagnetic wave in the band gap frequency range may further be enhanced.

Since the first conductors 2 and the third conductor 3 are electrically connected by the connective conductors 4 while being partially overlapped in the structure 100, so that the occupied area will not increase. In addition, since the regions t1 and t2 configure a parallel resonant circuit, electromagnetic wave in a set range of resonant frequency may be cut off. Accordingly, desired filter characteristics may be obtained without increasing the occupied area.

The band gap frequency range of the structure 100 may be lowered by enlarging the area of the overlapped region of the first conductor 2 and the third conductor 3. The area of the overlapped region of the first conductor 2 and the third conductor 3 may be adjustable typically by the area of the third conductor 3. Accordingly, the planar area of the structure 100 does not increase even if the area of the overlapped region of the first conductor 2 and the third conductor 3 increases.

### Second Embodiment

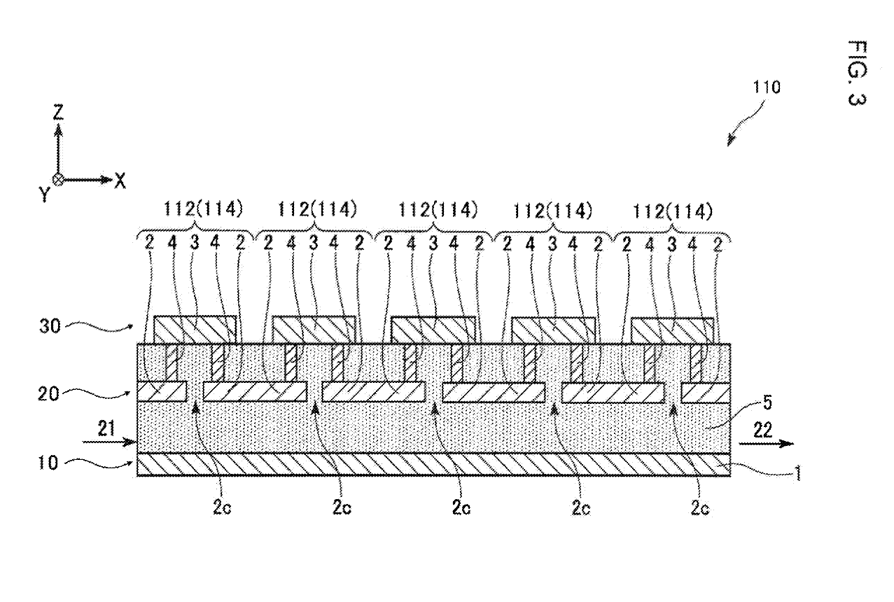

FIG. 3 is a sectional view illustrating a configuration of a structure 110 of the second embodiment. The structure 110 is configured by arranging a plurality of either ones of unit cells 112 and unit cells 114 in a repetitive manner, typically so as to show a periodical linear arrangement or two-dimensional arrangement. In every adjacent unit cell 112 (or unit cell 114) in the structure 110, one of the first conductors 2 of the unit cell 112 (or unit cell 114) serves as the other one of the first conductors 2 of the adjacent unit cell 112 (or unit cell 114), in the X-direction and Y-direction.

In this case, the plurality of first conductors 2 are located in the first layer 20, and are repetitively arranged, typically in a periodical pattern, while being separated from each other. The second conductor 1 spreads like a sheet over the region opposed to the plurality of first conductors 2. Each of the plurality of third conductors 3 is arranged so as to be overlapped, in a plan view, with two adjacent first conductors 2.

Now for the case where the unit cells 112 (or 114) are arranged in a “repetitive” manner, distance between the same vias (center-to-center distance) in the adjacent unit cells 112 (or 114) is preferably adjusted so as not to exceed ½ of wavelength λ of the electromagnetic wave predicted as noise. “Repetitive” herein covers the case where a part of configuration is omitted in any one of the unit cells 112 (or 114). For an exemplary case where the unit cells 112 (or 114) are arranged in a two-dimensional manner, “repetitive” covers the case where the unit cells 112 (or 114) are partially omitted. On the other hand, “periodicity” covers the case where a part of the constituents dislocates in, a part of the unit cells 112 (or 114), and the case where a part of the unit cells 112 (or 114) per se dislocates. In short, “periodicity” allows a certain degree of defects, since characteristics of the meta-material may be obtained so long as the unit cells 112 (or 114) are repetitively arranged, even if the periodicity in the strict sense should otherwise be degraded. Possible reasons for causing the defects include the case where interconnects or vias are laid between the unit cells, the case where the unit cells cannot be arranged making use of existing vias or patterns in the process of adding the meta-material structure to an existing interconnect layout, the case where manufacturing errors occur, and the case where existing vias or patterns are used as a part of the unit cells.

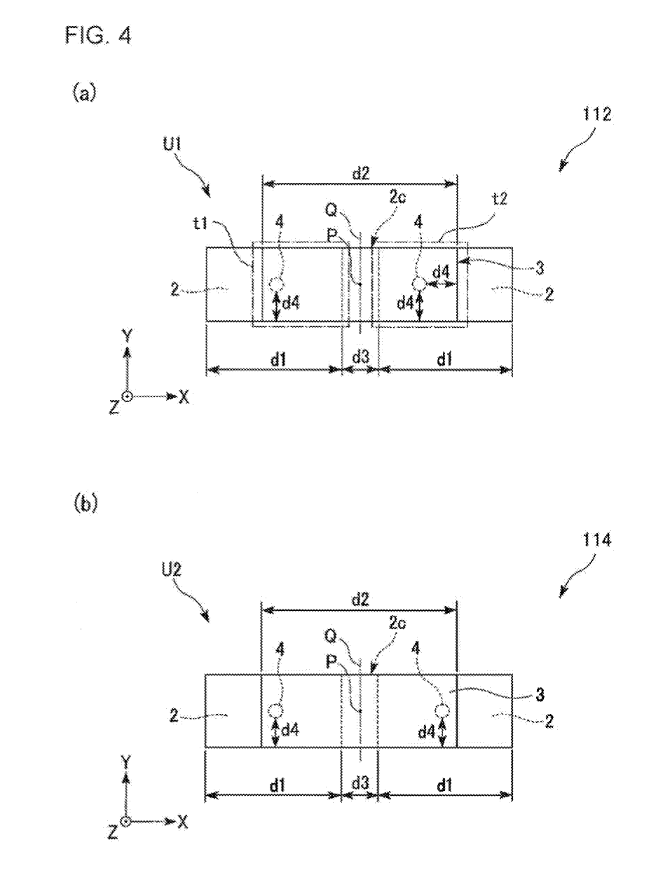

FIG. 4(a) is a plan view illustrating a configuration of the unit cell 112, and FIG. 4(b) is a plan view illustrating a configuration of the unit cell 114. The drawings correspond to FIG. 1(b) in the first embodiment. As illustrated in FIG. 4(a), the unit cell 112 is configured to arrange the connective conductors 4 laterally asymmetrical (non-line-symmetric) about the reference plane Q (that is, a line which is orthogonal to the first line and passes the center of the slit 2c). In other words, at least two connective conductors 4 connected to the same third conductor 3 are arranged neither line-symmetric nor point-symmetric with each other about the center of the third conductor 3. On the other hand, as illustrated in FIG. 4(b), the unit cell 114 is configured to arrange the connective conductors 4 laterally symmetrical (line-symmetric about the reference plane Q in a plan view).

More specifically, in the example illustrated in FIG. 4(a), the connective conductor 4 in the region t1 is located in the vicinity of an edge of the third conductor 3 which does not cross the reference plane Q. On the other hand, the connective conductor 4 in the region t2 is located closer to the center of the third conductor 3, as compared with the connective conductor 4 in the region t1.

In the individual cases where the structure 100 is configured by the unit cells 112 and the unit cells 114, absolute values of transmission coefficient were calculated using publicly-known analytical techniques exemplified in References 1 to 3 below, while assigning reference numeral 21 to the power input side, and reference numeral 22 to the power output side, as illustrated in FIG. 3. The transmission coefficient herein means an index which indicates a ratio of output power to the input power. In this example, an absolute value of S parameter (S21) in a 50-ohm input/output system was adopted. The analytical technique aims at determining an equivalent circuit model, by dividing a space between the opposing conductors into a fine mesh, and by expressing a circuit constant of each mesh by the equation (1) below. The analysis was carried out while assuming d1=d2=8 mm and d3=d4=2 mm in the individual drawings of FIG. 4.

$$\begin{matrix}[ Mathematical Formula 1 ] & \\ C = {ɛ}_{0} {ɛ}_{r} \frac{{l}^{2}}{t} [ F ] , L = {μ}_{0} t [ H ] , R = 2 \frac{ρ}{s} [ Ω ] , & ( 1 )\end{matrix}$$

C: capacitance
L: inductance
R: resistance
ε: dielectric constant
l: width
t: length between conductive layers
μ: magnetic permeability
ρ: resistance per unit length
s: depth

### [Reference 1]

EMC Europe 2008 International Symposium on Electromagnetic Compatibility Proceedings 1, pp. 97-102, “Analysis of a PCB-Chassis System Including Different Sizes of Multiple Planes Based on SPICE”

### [Reference 2]

EMC Europe 2004 International Symposium on Electromagnetic Compatibility, “Optimization of Decoupling Capacitor Allocations in Relation to LSI Chips for Suppressing Voltage Disturbances in Power Distribution Systems”, Volume 1, pp. 460-463

### [Reference 3]

Japanese Patent Application No. 2006-336423

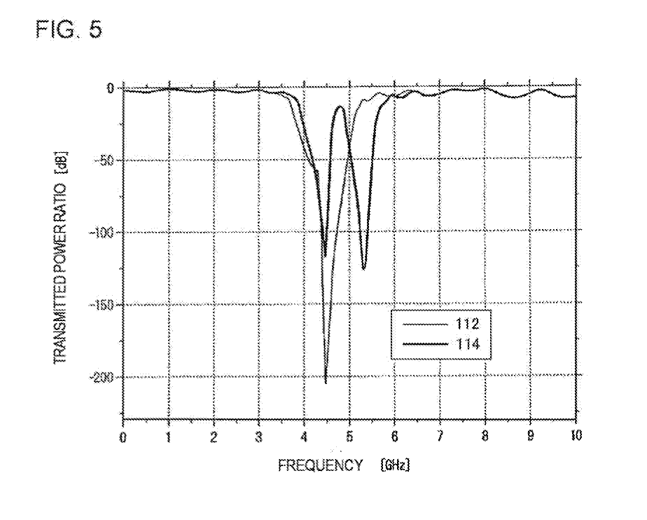

Results of calculation of absolute values of the transmission coefficient are shown in FIG. 5. FIG. 5 teaches that the structure 110 configured by the unit cells 114 functions as a filter having two band gap frequency ranges up to a frequency range of 10 GHz, whereas the structure 110 configured by the unit cells 112 functions as a filter having a single cut-off frequency range.

A reason why the structure 110 configured by the unit cells 114 has two band gap frequency ranges will be explained. As previously discussed referring to FIG. 2(b), the resonant frequency of the equivalent circuit T1 is determined by the individual values of C₁, C₃, R₁ and L₁, whereas the resonant frequency of the equivalent circuit T2 is determined by the individual values of C₂, C₄, R₂ and L₂. For the case where the resonant frequencies are different from each other, a band gap frequency range appears corresponding to each of the resonant frequencies. It is apparent from comparison between the region t₁ corresponded to the equivalent circuit T1 and the region t₂ corresponded to the equivalent circuit T2 in the unit cell 114, that positions of the connective conductors 4 are laterally asymmetrical. Accordingly, R₂ and L₂ illustrated in FIG. 2(b) will have values different from those of R₁ and L₁. As a consequence, the structure 110 configured by the unit cells 114 has two band gap frequency ranges.

As described in the above, according to this embodiment, effects similar to those of the first embodiment may be obtained. The band gap frequency range may be set in a desired frequency range by adjusting the position of the connective conductors 4. The structure 110 may be given a plurality of band gap frequency ranges by arranging the connective conductors 4 in a laterally asymmetrical manner. This effect is advantageous typically for the case where a filter for removing unnecessary electromagnetic wave is configured using the structure 110.

### Third Embodiment

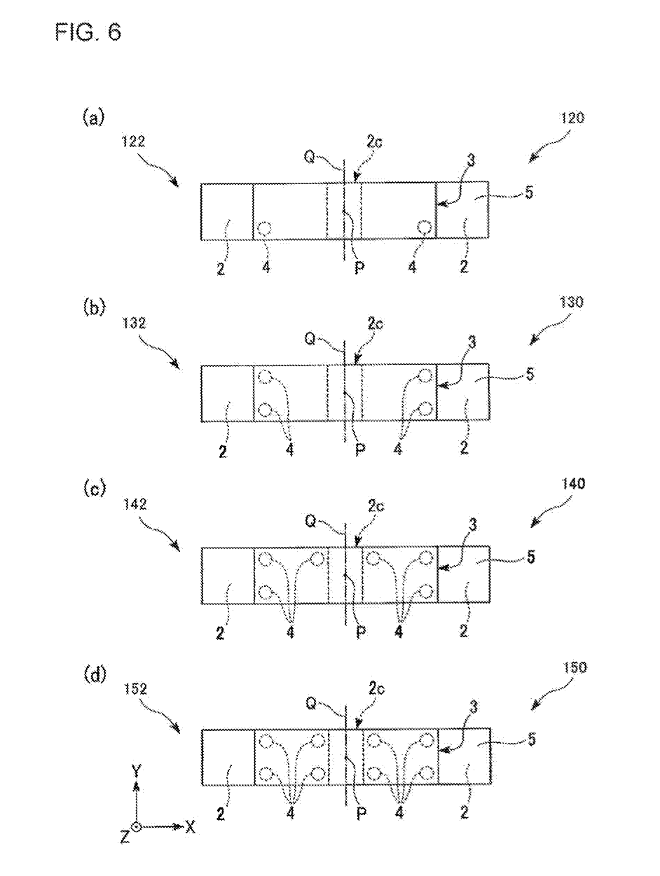

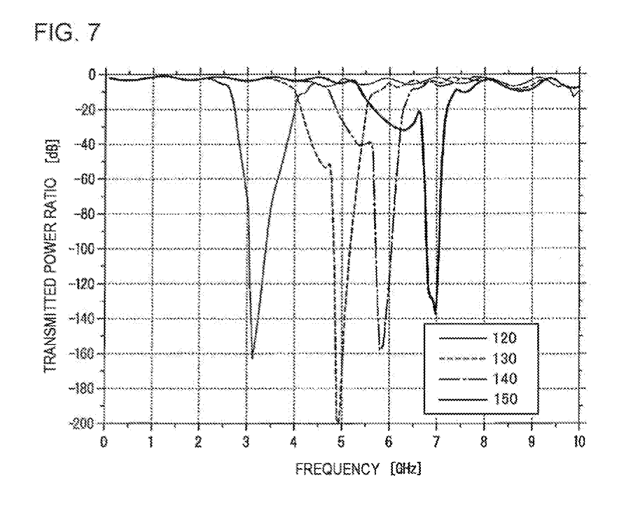

FIG. 6 and FIG. 7 are drawings explaining structures 120, 130, 140 and 150 of the third embodiment. This embodiment will explain possibility of adjustment of the band gap frequency range of the structures 100, 110 previously explained in the first and second embodiments. Note that all constituents similar to those in FIGS. 1 to 5 will be given the same reference numerals or symbols, so as to avoid repetitive explanation.

FIGS. 6(a) to (d) are partial plan views of the structures 120, 130, 140 and 150, respectively. The structures 120, 130, 140, 150 have unit cells 122, 132, 142 and 152, respectively. Each of the unit cells 122, 132, 142 and 152 is configured to arrange the connective conductors 4 laterally symmetrical (line-symmetric in a plan view) about the reference plane Q. The number of connective conductor 4, per combination of one of the first conductors 2 and one third conductor 3, is one for the unit cell 122, two for the unit cell 132, three for the unit cell 142, and four for the unit cell 152. In each of the unit cells 122, 132, 142 and 152, each overlapped portion of the first conductor 2 and the third conductor 3 has a rectangular or square geometry, wherein the connective conductors 4 are arranged at the corner(s) of the overlapped portion.

FIG. 7 illustrates, similarly to FIG. 5, results of calculation of absolute values of transmission coefficients of the structures 120, 130, 140 and 150 respectively having five unit cells 122, 132, 142 and 152 connected in series. FIG. 7 teaches that the band gap frequency range shifts towards high frequency side as the number of connective conductors 4 increases. As is clear from the above, the band gap frequency range may be adjustable also by varying the number of connective conductors 4. Accordingly, the band gap frequency range may be adjustable to a frequency of electromagnetic wave desired to be cut off, by setting the number of the connective conductors 4.

### Fourth Embodiment

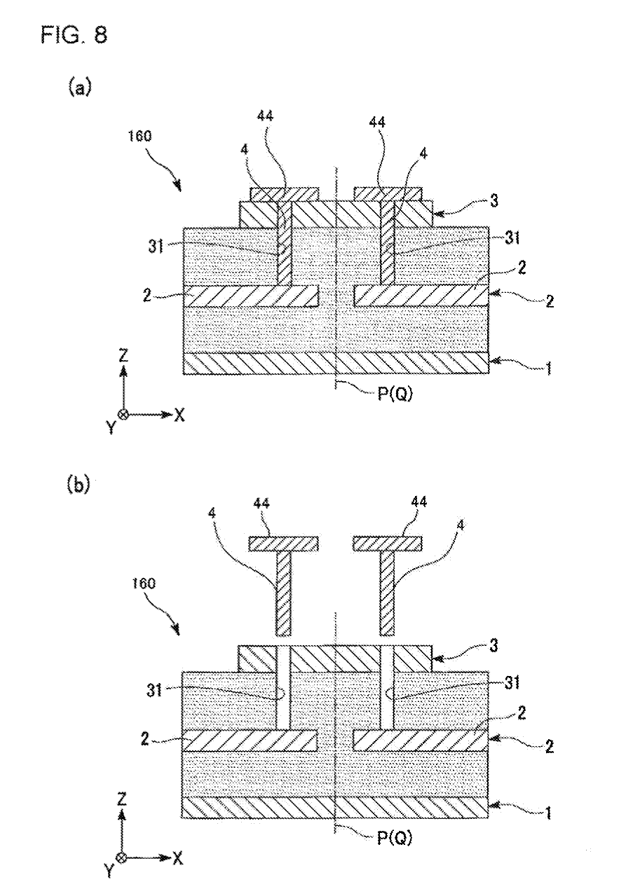

FIG. 8 is a sectional view illustrating a configuration of a structure 160 of the fourth embodiment. The structure is similar to the structure 100 described in the first embodiment and the structure 110 described in the second embodiment, except for the aspects below.

First, the third conductor 3 has third openings 31. The third openings 31 are provided so as to allow therethrough insertion of the connective conductors 4 from the opposite side of the first conductors 2. Each connective conductor 4 has an open end at one end, and has a stopper 44 at the other end. Plane geometry of the stopper 44 is larger than that of the third opening 31. Distance between the open end of the connective conductor 4 and the back surface of the stopper 44 is set equal to distance between the top surface of the third conductor 3 and the top surface of the first conductor 2. Accordingly, by inserting the connective conductor 4 into the third opening 31 so as to bring the back surface of the stopper 44 into contact with the top surface of the third conductor 3, the open end of the connective conductor 4 comes into contact with the top surface of the first conductor 2.

In this embodiment, a plurality of third openings 31 are formed, for example, at the positions where the connective conductors 4 are provided as illustrated in any one of FIGS. 6(b) to (d). The band gap frequency range may be adjustable even after the body of the structure 160 was manufactured, by adjusting the number and the positions of the third openings 31 in which the connective conductors 4 are inserted. For example, by arranging the connective conductors 4 at the same respective positions illustrated in FIGS. 6(b), (c) and (d), the structure 160 will have the same characteristics with those of the structures 130, 140 and 150. In other words, the structures 130, 140 and 150 different from each other may be manufacturable by using a common body of structure. Accordingly, the labor and cost for designing of the structure, and cost for manufacturing of the structure may be saved.

### Fifth Embodiment

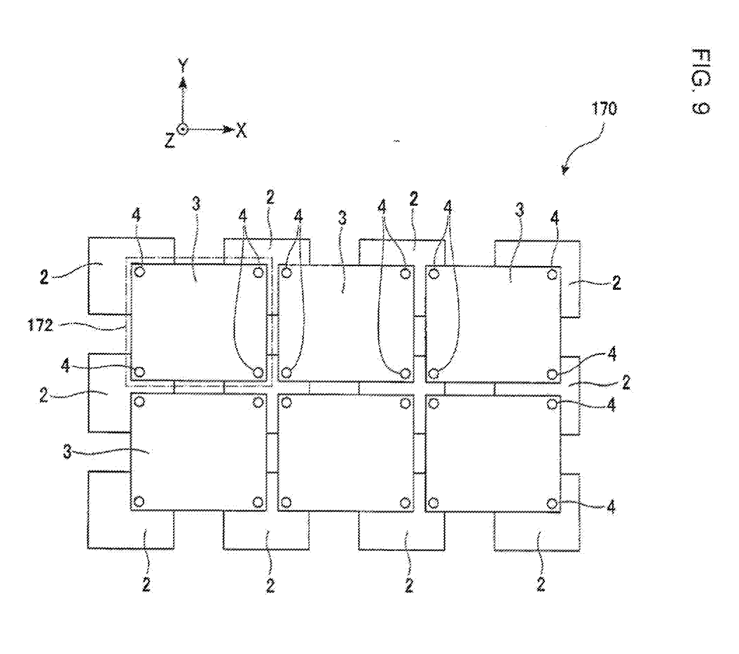

FIG. 9 is a plan view illustrating a configuration of a structure 170 of the fifth embodiment. In this embodiment, the structure 170 is configured to arrange unit cells 172 in the two-dimensional direction (XY-direction), and may be used typically as a filter capable of blocking propagation of electromagnetic wave in a two-dimensional direction, at a specific frequency.

For more details, the unit cell 172 is configured by four first conductors 2 arranged in a two-row-two-column array, the third conductor 3 arranged so as to bridge four first conductors 2, and the connective conductors 4 electrically connecting each of four first conductors 2 to the third conductor 3. The structure 170 is configured by arranging a plurality of unit cells 172 in a repetitive manner, typically in a periodical manner, in the XY-direction. In every adjacent unit cells 172, two of the first conductors 2 of one unit cell 172 serve as the other two of the first conductors 2 of the other unit cell 172. In the illustrated example, the first conductors 2 and the third conductors 3 have rectangular geometries, where one of the third conductors 3 overlap a quarter region, including a corner, of one first conductor 2. Each connective conductor 4 is provided at a position which overlaps each corner of the third conductor 3. The first conductor 2 and the third conductor 3 may alternatively have any other arbitrary polygonal geometry such as hexagon.

In other words, in a plan view, the plurality of first conductors 2 are arranged in a matrix while keeping a space in between, and the third conductors 3, which are similarly arranged in a matrix while keeping a space in between, are stacked while being staggered with the first conductors 2.

According to this embodiment, effects similar to those in the first embodiment may be obtained. In addition, propagation of electromagnetic wave in two-dimensional direction may be blocked at a specific frequency.

### Sixth Embodiment

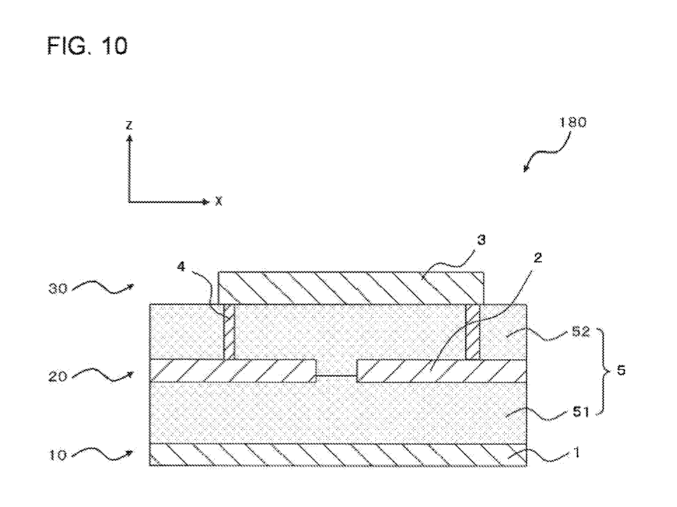

FIG. 10 is a vertical sectional view illustrating a configuration of a structure 180 of the sixth embodiment. The structure 180 is configured similarly to those described in any one of the first to fifth embodiments, except that the dielectric layer 5 is configured by a first dielectric layer 51 and a second dielectric layer 52.

The first dielectric layer 51 fills up the space between the first layer 20 and the second layer 10, and the second dielectric layer 52 fills up the space between the first layer 20 and the third layer 30. The first dielectric layer 51 has a dielectric constant different from that of the second dielectric layer 52.

According to this embodiment, effects similar to those in the first embodiment may be obtained. In addition, the values of the first capacitances C₁ and C₂ in the equivalent circuit illustrated in FIG. 2(b) may be adjustable, by altering a material for composing the second dielectric layer 52 to thereby adjust the dielectric constant thereof. Accordingly, the band gap frequency range inherent to the structure 180 may be adjustable. For example, by selecting a material for composing the second dielectric layer 52 so as to make the dielectric constant of the second dielectric layer 52 larger than that of the first dielectric layer 51, the band gap frequency range of the structure 180 may be lowered, as compared with the case where all of the dielectric layers 5 were configured by the material same as that composing the first dielectric layer 51.

### Seventh Embodiment

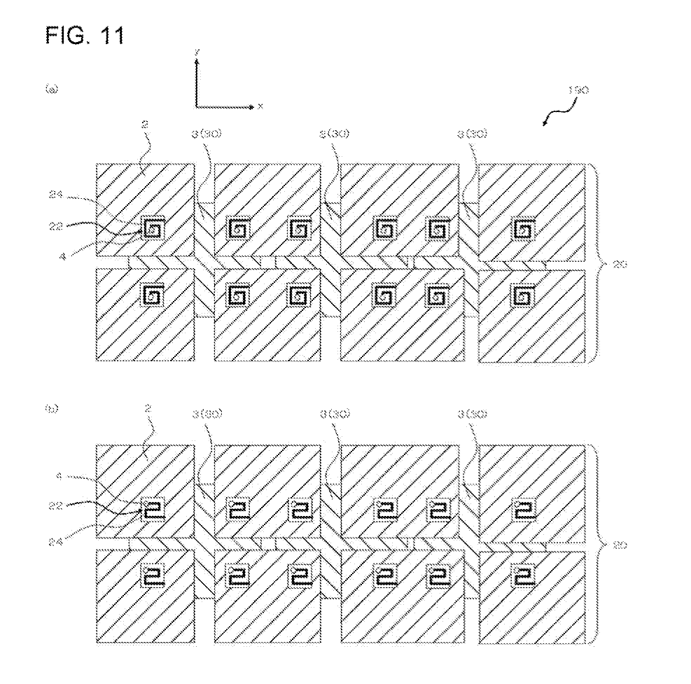

FIG. 11(a) is a plan view illustrating a configuration of a structure 190 of the seventh embodiment. The drawing illustrates a view taken from the back side of the first layer 20 looked upward (or looked towards the third layer 30). The structure 190 is configured similarly to the structure 170 of the fifth embodiment, except for the aspects below.

First, the first conductors 2 have first openings 22 and the fourth conductors 24 formed therein. Each first opening 22 is formed in a region which overlaps each connective conductor 4 in a plan view. Each fourth conductor 24 has an line pattern, and connects the first conductor 2 and the connective conductor 4. In this example, excluding the first conductors 2 at both ends, every first conductor 2 is provided with a plurality of connective conductors 4. The first opening 22 and the fourth conductor 24 are provided to the regions corresponded to all connective conductors 4. Note that the first openings 22 and the fourth conductors 24 may alternatively be provided to the regions corresponded only to a part of the connective conductors 4.

In the illustrated example, each first opening 22 has a square geometry, and has the connective conductor 4 positioned at the center thereof. The fourth conductor 24 extends around the connective conductor 4 in a spiral manner, in a plan view.

FIG. 11(b) is a plan view illustrating a modified example of FIG. 11(a). In the illustrated example, the connective conductor 4 in a plan view is decentered in each first opening 22. The fourth conductor 24 extends in the first opening 22 in a meandering or zigzag manner.

Effects similar to those in the fifth embodiment may be obtained also by this embodiment. Since the line-like fourth conductors 24 are located between the connective conductors 4 and the first conductors 2, inductances L₁, L₂ and resistances R₁, R₂ in the equivalent circuit illustrated in FIG. 2(b) become larger. Accordingly, the band gap frequency range of the structure 190 may be made lower than that of the structure 170.

Note that, also in the first to fourth embodiments and in the sixth embodiment, the first openings 22 and the fourth conductors 24 may be provided, similarly to this embodiment.

### Eighth Embodiment

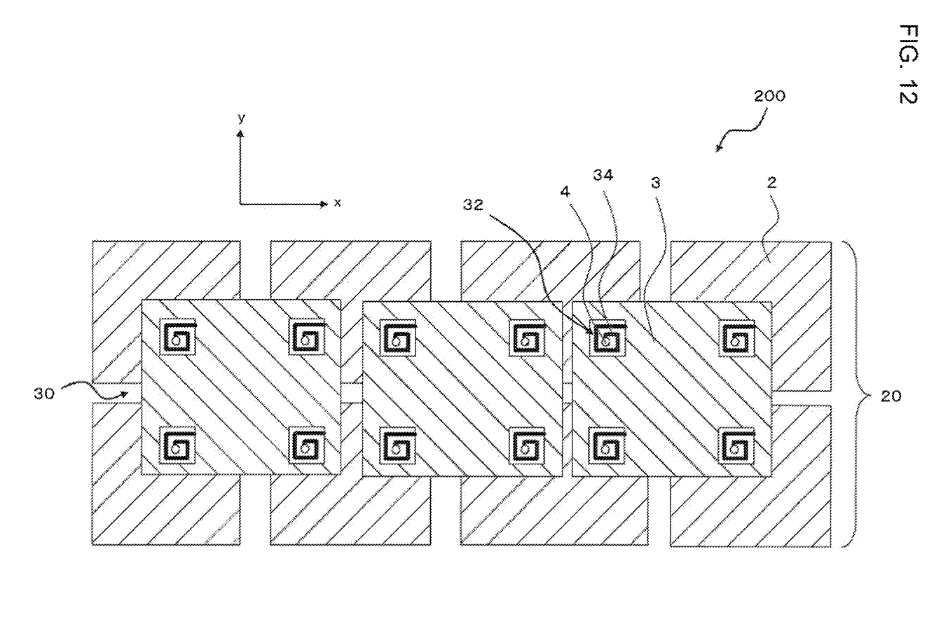

FIG. 12 is a plan view illustrating a configuration of a structure 200 of the eighth embodiment. The drawing illustrates a view taken from the top side of the third layer 30 looked downward (or looked towards the first layer 20). The structure 200 is configured similarly to the structure 170 of the fifth embodiment or to the structure 190 of the seventh embodiment, except that second openings 32 and fifth conductors 34 are provided to the third conductors 3. Layout and geometry of the second openings 32 and the fifth conductors 34 in the third conductors 3 are similar to those of the first openings 22 and the fourth conductors 24 described in the seventh embodiment. While the fifth conductors 34 illustrated in this drawing extend in a spiral manner, they may extend in a meandering manner similarly to the fourth conductors 24 illustrated in FIG. 11(b).

Effects similar to those of the seventh embodiment may be obtained also by this embodiment.

Note that the second openings 32 and the fifth conductors 34 may be provided also to the first to fourth embodiments and to the sixth embodiment, similarly to this embodiment.

### Ninth Embodiment

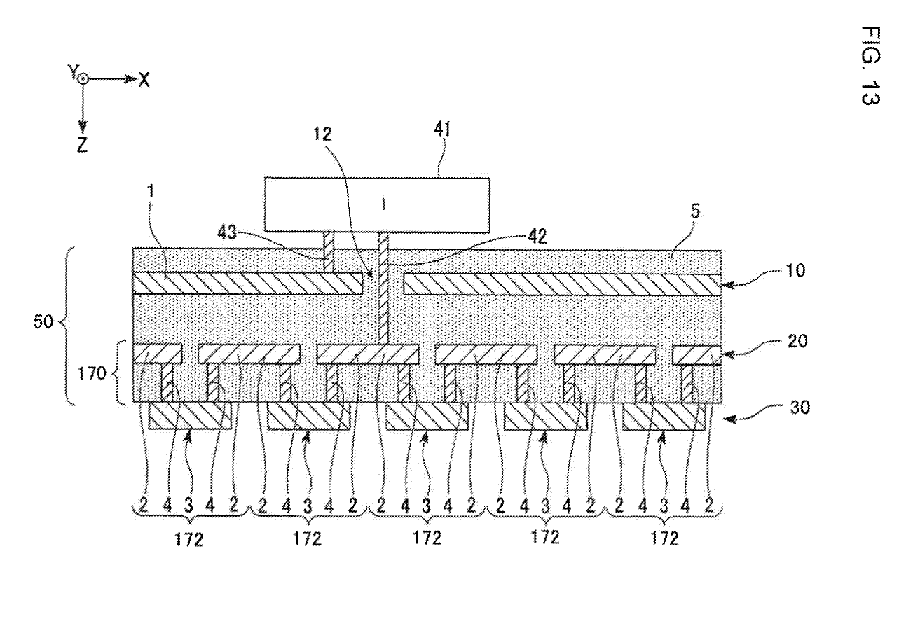

FIG. 13 is a drawing illustrating a configuration of an electronic device of the ninth embodiment. The electronic device has a semiconductor package 41 as an example of the electronic element, and a circuit board 50. The circuit board 50 has the structure explained in any one of the first to eighth embodiments. In the illustrated example in FIG. 13, the circuit board 50 has a configuration similar to that of the structure 170 explained in the fifth embodiment.

For more details, the structure 170 is formed in a region which overlaps the semiconductor package 41 in a plan view. The second conductor 1 of the structure 170 serves as either one of the ground plane and the power plane of the circuit board 50, and the first conductors 2 serve as the other one of the ground plane and the power plane of the circuit board 50. The third conductors 3 are formed on one surface (the back surface in the illustrated example) of the circuit board 50. The semiconductor package 41 is mounted on the other surface (the top surface in the illustrated example) of the circuit board 50. In this illustrated example, the third conductors 3, the first conductors 2, the second conductor 1, and the semiconductor package 41 are stacked in this order.

The circuit board 50 has vias 42 and 43 provided thereto. The via 42 connects the semiconductor package 41 to the first conductor 2, and the via 43 connects the semiconductor package 41 to the second conductor 1. In other words, the semiconductor package 41 is supplied with source potential through either one of the vias 42 and 43, and with the ground potential through the other one.

The second conductor 1 has an opening 12 in the region which overlaps the via 42 in a plan view. By providing the opening 12, the via 42 may connect the semiconductor package 41 and the first conductor 2, without causing short-circuiting with the second conductor 1.

According to this embodiment, the second conductor 1 serves as either one of the ground plane and the power plane of the circuit board 50, and the first conductors 2 serve as the other one of the ground plane and the power plane of the circuit board 50. In other words, the structure 170 is configured by using the ground plane and the power plane of the circuit board 50. Accordingly, even if the band gap frequency range inherent to the structure 170 covers frequency of noise ascribable to the semiconductor package 41, the noise emitted from the semiconductor package 41 may be suppressed from propagating to the ground plane and the power plane. In addition, even if the band gap frequency range of the structure 170 covers frequency of noise which is not welcomed by the semiconductor package 41, the noise may be suppressed from entering the semiconductor package 41 through the ground plane and through the power plane.

As described in the above, by using the circuit board 50 of this embodiment, electromagnetic wave may be allowed to transmit on the transmission line without increasing the area for mounting, while successfully blocking propagation of electric signals of a specific frequency and electromagnetic noise, and thereby interference by any unnecessary electromagnetic wave may be suppressed.

Embodiments of the present invention were explained referring to the attached drawings merely as exemplary purposes, while allowing various configurations other than those described in the above.

This application claims priority right based on Japanese Patent Application No. 2008-269126 filed on Oct. 17, 2008, the entire content of which is incorporated hereinto by reference.

1. A structure comprising:
a plurality of first conductors which are located in a first layer and are repetitively arranged while being separated from each other;
a second conductor which is located in a second layer different from said first layer, and is provided so as to have at least a part thereof in a region opposed to said plurality of first conductors;
a third conductor which is located in a third layer located opposite to said second layer while placing said first layer in between, and is opposed to each of said plurality of first conductors placed adjacent to each other; and
a plurality of connective conductors which connect said third conductor with said plurality of first conductors opposed to said third conductor.

2. The structure as claimed in claim 1,
wherein distance between said first conductors and said third conductor is larger than distance between the end faces of said plurality of first conductors placed adjacent to each other.

3. The structure as claimed in claim 1,
wherein each of said plurality of first conductors placed adjacent to each other has the same area of regions thereof opposed to said third conductor.

4. The structure as claimed in claim 1,
wherein said plurality of connective conductors are provided to a combination of one of said first conductors and one said third conductor.

5. The structure as claimed in claim 1, further comprising:
a first dielectric layer which is located between said first layer and said second layer; and
a second dielectric layer which is located between said first layer and said third layer,
wherein said second dielectric layer has a dielectric constant larger than that of said first dielectric layer.

6. The structure as claimed in claim 1, further comprising:
a first opening which is formed in said first conductors, and is opposed to said connective conductors; and
an line-like fourth conductor which is provided in said first opening, and connects said first conductors and said connective conductors.

7. The structure as claimed in claim 6,
wherein said fourth conductor extends in said first opening in a meandering manner or in a spiral manner.

8. The structure as claimed in claim 1, further comprising:
a second opening which is provided in said third conductor, and is opposed to said connective conductors; and
an line-like fifth conductor which is provided in said second opening, and connects said third conductor and said connective conductors.

9. The structure as claimed in claim 8,
wherein said fifth conductor extends in said second opening in a meandering manner or in a spiral manner.

10. The structure as claimed in claim 1,
wherein said plurality of connective conductors connected to the same third conductor are arranged neither line-symmetric nor point-symmetric with each other about the center of said third conductor.

11. The structure as claimed in claim 1,
wherein said third conductor has a plurality of third openings which allow therethrough insertion of said connective conductors from the opposite side of said first conductors, in such a way that said connective conductors are inserted into at least one of said third openings in said third conductor, so as to connect said third conductor and said first conductors.

12. The structure as claimed in claim 11,
wherein said connective conductors are inserted into said third openings in a freely detachable manner.

13. An electronic device comprising:
an electronic element; and
a circuit board hiving said electronic element mounted thereon,
said circuit board comprising:
a plurality of first conductors which are located in a first layer and are repetitively arranged while being separated from each other;
a second conductor which is located in a second layer different from said first layer, and is provided so as to have at least a part thereof in a region opposed to said plurality of first conductors;
a plurality of third conductors which are located in a third layer located opposite to said second layer while placing said first layer in between, and are opposed to each of said plurality of first conductors placed adjacent to each other; and
a plurality of vias which connect said respective third conductors with said plurality of first conductors opposed to said third conductors,
wherein either one of said first layer and said second layer has a power source pattern through which source potential is supplied to said electronic element, and the other has a ground pattern through which ground potential is supplied to said electronic element.

14. A circuit board comprising:
a plurality of first conductors which are located in a first layer and are repetitively arranged while being separated from each other;
a second conductor which is located in a second layer different from said first layer, and is provided so as to have at least a part thereof in a region opposed to said plurality of first conductors;
a plurality of third conductors which are located in a third layer located opposite to said second layer while placing said first layer in between, and are opposed to each of said plurality of first conductors placed adjacent to each other; and
a plurality of vias which connect said respective third conductors with said plurality of first conductors opposed to said third conductors,
wherein either one of said first layer and said second layer has a power source pattern through which source potential is supplied, and the other has a ground pattern through which ground potential is supplied.
